(19) United States
(12) Patent Application Publication
(10) Pub. No.: US 2008/0304239 A1
(43) Pub. Date: Dec. 11, 2008

(54) Electrical card connector

(75) Inventors: Yung-Chang Cheng, Tu-cheng (TW); Jian-Long Wei, Kunshan (CN)

Correspondence Address: WEI TE CHUNG;FOXCONN INTERNATIONAL, INC., 1650 MEMOREX DRIVE, SANTA CLARA, CA, 95050, US

(73) Assignee: HON HAI PRECISION IND. CO., LTD.

(21) Appl. No.: 12/157,655

(22) Filed: Jun. 11, 2008

(30) Foreign Application Priority Data
Jun. 11, 2007 (TW) 96209537

(51) Int. Cl. H05K 7/14; H01R 13/62

(52) U.S. Cl. 361/726; 439/153

(57) ABSTRACT

An electrical card connector (100) includes a connector body (1) mounted a plurality of terminals (11) therein. A pair of guiding arms (21) are arranged on opposite sides of the connector body (1) and defines a receiving space between the connector body (1) and the guiding arms (21). An ejector (3) is assembled on one guiding arm (21) and comprises a pushing mechanism (302) and an ejecting mechanism (301). The pushing mechanism (302) comprises a metal bracket (31), a pushing portion and a body portion (34) defining a guiding groove (341) therein. One end of the body portion (34) is retained on the guiding arm (21) and the other end of the body portion (34) is retained by the bracket (31), so the bracket (31) keeps the pushing mechanism (302) being retained on the guiding arm (21).

### BACKGROUND OF THE INVENTION

1. Field of the Invention

The present invention relates to an electrical connector, and particularly to an electrical card connector including a card ejecting device.

2. Description of the Related Art

A conventional electrical card connector includes an insulating base portion with a plurality of terminals mounted thereon and an ejector assembled on a lateral side of the base portion. The ejector includes a pushing mechanism and an ejecting mechanism. The pushing mechanism includes a pushing rod, a metallic bracket and a body portion with a guiding groove therein. In order to mount the body portion onto a lateral side of the base portion, at least two solder tails are provided to fix two opposite ends of the body portion. However, the multi-soldering process of the at least two solder tails is complex. Therefore, a new design which can solve the problem is provided.

### SUMMARY OF THE INVENTION

Accordingly, an object of the present invention is to provide an electrical card connector comprising a body portion with a guiding groove therein, wherein the body portion is simply assembled on a shell of the card connector.

In order to achieve the object set forth, an electrical card connector comprises a connector body mounted a plurality of terminals therein. A pair of guiding arms are arranged on opposite sides of the connector body and defines a receiving space between the connector body and the guiding arms. An ejector is assembled on one guiding arm and comprises a pushing mechanism and an ejecting mechanism. The pushing mechanism comprises a metal bracket, a pushing portion and a body portion defining a guiding groove therein. One end of the body portion is retained on the guiding arm and the other end of the body portion is retained by the bracket, so the bracket keeps the pushing mechanism being retained on the guiding arm.

Other objects, advantages and novel features of the invention will become more apparent from the following detailed description of the present embodiment when taken in conjunction with the accompanying drawings.

### BRIEF DESCRIPTION OF THE DRAWINGS

FIG. 1 is a perspective view of one embodiment of an electrical card connector in accordance with the present invention;

FIG. 2 is an exploded view of the electrical card connector shown in FIG. 1;

FIG. 3 is an exploded view of a pushing mechanism of the electrical card connector;

FIG. 4 is another exploded view of the pushing mechanism; and

FIG. 5 is a perspective view of the pushing mechanism.

### DETAILED DESCRIPTION OF THE INVENTION

Reference will now be made to the drawing figures to describe a preferred embodiment of the present invention in detail.

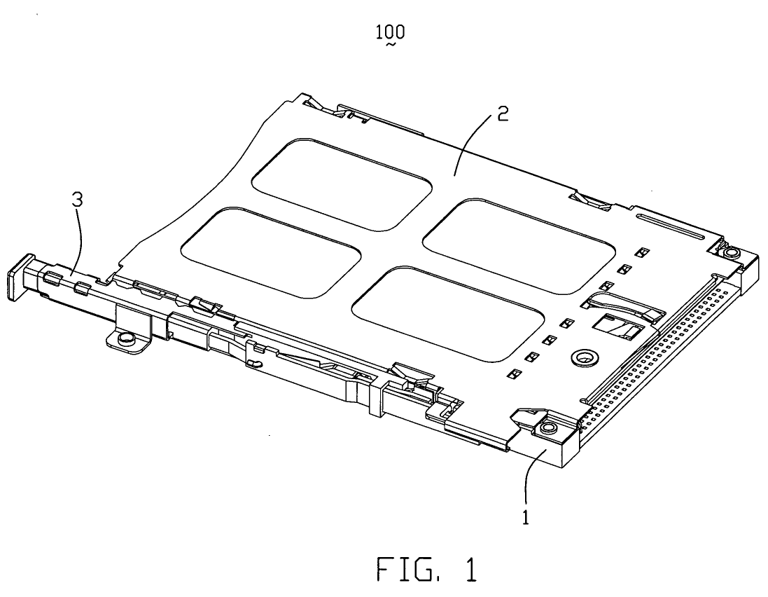

Referring to FIG. 1, an electrical card connector 100 according to the present invention is provided and comprises a connector body 1, a shell 2 covering the connector body 1 and an ejector 3 assembled on one side of the shell 2.

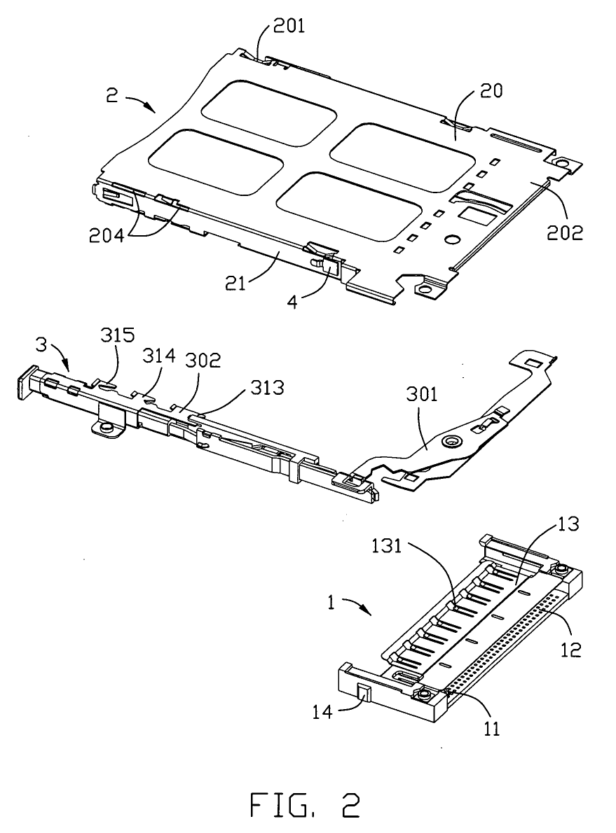

Referring to FIG. 2, the connector body 1 is in an elongated shape. A plurality of conductive terminals 11 is arranged in the body with soldering legs extending rearward and positioned in a positioning board 12 at a rear portion of the body. A grounding plate 13 is covered on the connector body 1 and forms a plurality of spring terminals 131 extending forward. A protrusion portion 14 is formed on a lateral side of the body 1.

The metallic shell 2 comprises a base portion 20 and a pair of side walls 21 extending downwardly and perpendicularly from sides of the base portion 20. The shell 2 is covering the connector body 1 and a receiving space is defined between the side walls 21 and the connector body 1 for receiving an electrical card (not shown). The side walls 21 serve as guiding arms for the electrical card and the guiding arms can be separately made in alternative embodiment. A plurality of spring tabs 201 projects downward into the receiving space at edges of the base portion 20 so as to engage with a top surface of the electrical card. The front portion 202 of the shell 2 is defined as a mounting end and the other end is used as mating opening. Two openings 204 are defined at edges of the base portion 20 near the mating opening.

The ejector 3 mainly includes an ejecting mechanism 301 made of metal sheet and a pushing mechanism 302. The ejecting mechanism 301 is sandwiched between the mounting end 202 of the shell 2 and the connector body 1 and the pushing mechanism 302 is assembled on one side wall 21 of the shell 2, after the shell 2 is fixed on the connector body 1 by a pair of screws (not shown). A detailed description of the fabric of the pushing mechanism 302 will be given hereafter.

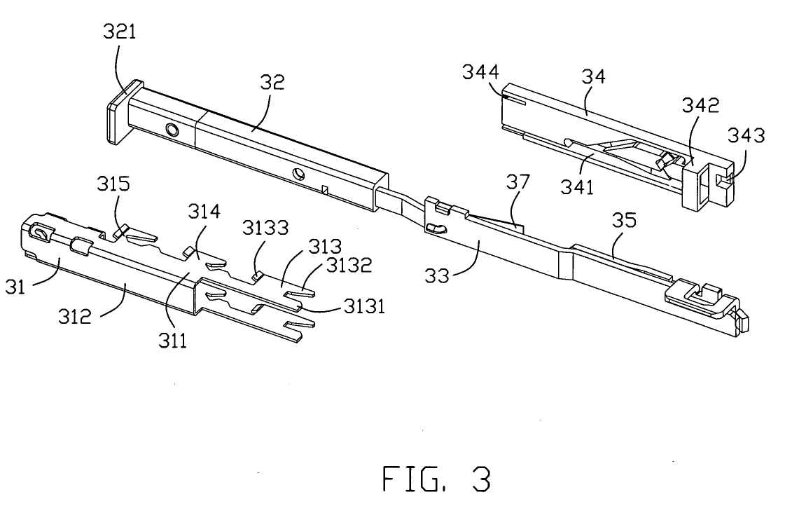

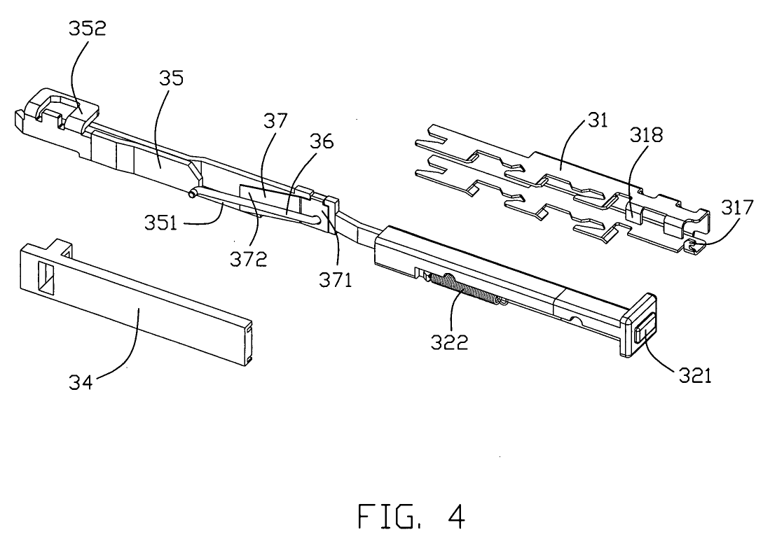

Referring to FIGS. 3 and 4, the pushing mechanism 302 includes a metal bracket 31, a pushing rod 32, a driving device 33, a body portion 34, a passive device 35, a slider 36 and a supporting plate 37.

In this embodiment, the metal bracket 31 is made of a metal sheet and includes a top and a bottom wall 311 parallel to each other and an side wall 312 connecting the top and bottom wall 311. The front portions of the top and bottom walls 311 are in a fork shape and define a retaining portion 3131 adjacent to the side wall 312 and a first locking portion 313 at opposite side to the retaining portion 3131. A locking arm 3132 is formed in a front portion of the first locking portion 313, and a tab 3133 protruding upwardly is formed in a rear portion of the first locking portion 313. A second locking portion 314 and a third locking portion 315 similar to the first locking portion 313 are arranged in line along the edges of the top and bottom walls behind the first locking portion 313.

The pushing rod 32 is in an elongated hollow post configuration and forms a button 321 at a distal end thereof. A coil spring 322 is provided with its one end locked with a hook 317 formed in an inner portion of the bracket 31 when the pushing rod 32 is received in the bracket 31 and the other end locked with an inner portion of the pushing rod 32. The driving device 33 is a flat longitudinal board with one end molded in the pushing rod 32. The driving device 33 can be urged to move forwardly or backwardly by the pushing rod 32, therefore the pushing rod 32 and the driving device 33 defines a pushing portion.

The body portion 34 is made of plastic material and in a rectangular shape. A heart shaped guiding groove 341 is defined at a middle portion of one side of the body portion 34. A receiving portion 342 with a through hole therein is formed on one end of the body portion 34, and an aperture 343 is defined at the free end adjacent to the receiving portion 342. The guiding groove 341 and the aperture 343 are respectively defined at opposite sides of the receiving portion 342. A pair of receiving slots 344 are respectively formed at an upper and a lower edge of the other free end of the body portion 34.

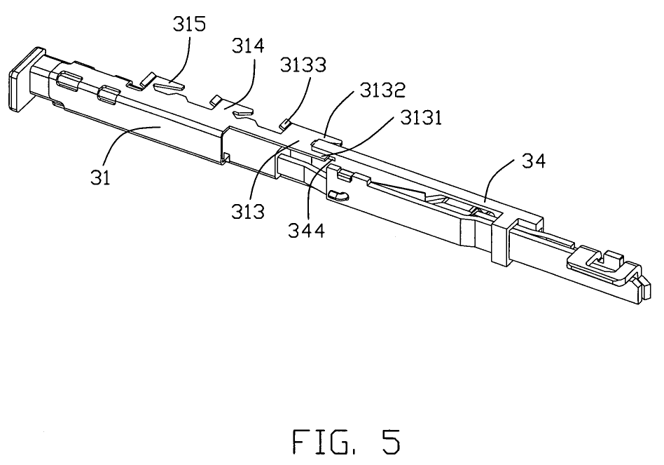

The passive device 35 is attached on the driving device 33 and forms a connecting portion 352 connecting with the pushing mechanism 302. The slider 36 is a metal stiff wire with two reversely bend distal ends. A supporting board 37 is provided with an end portion 371 retained in the driving device 33 and the other end portion 372 projecting upwardly to support the slider 36. The passive device 35 and driving device 33 surpass the through hole of the body portion 34 and the retaining portion 3131 of the metal bracket 31 is inserted into the receiving slot 344, meanwhile one end of the slider 36 is movably received in the guiding groove 341 thereby the pushing mechanism is formed as FIG. 5 shown.

Referring to FIG. 1, the third locking portion 315 of the metal bracket 31 is inserted into the front edge of the mating end of the shell 2, and the first and second locking portion 313, 314 are inserted into the opening 204 on the side wall 21 of the shell 2. The first locking arm 3132 of the first locking portion 313 is engaging with an inner wall of the side wall 21 and the tab 3133 is interfering with the base portion 20, therefore one end of the pushing mechanism 302 is assembled on the side wall 21 of the shell 2, i.e. one end of the body portion 34 is assembled on the side wall 21. A solder pad 4 is provided with main body soldered on the side wall 21 and solder tail received in the aperture 343, therefore, the other end of the body portion 34 is assembled on the side wall 21 of the shell. In other embodiment, the solder pad 4 can be replaced by a tab stamped from the side wall 21.

In this embodiment, one end of the body portion 34 is firstly retained by the bracket 31, and then the bracket 31 is assembled on the side wall 21 of the shell 2. Comparing with retaining one end of the body portion 34 by a solder pad, the present invention cancels the solder pad and made full use of the existing component, which is helpful to reduce the cost of production, moreover, the whole assemble process of the body portion 34 is simplified. In other embodiment, the driving device 33 forms a connecting portion in its distal end to connect with the ejecting mechanism 301 so that the passive device 35 can be canceled.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. An electrical card connector comprising:
a connector body mounted a plurality of terminals therein;
a pair of guiding arms arranged on opposite sides of the connector body and defining a receiving space between the connector body and the guiding arms;
an ejector assembled on one guiding arm and comprising a pushing mechanism and an ejecting mechanism, the pushing mechanism comprising a metal bracket, a pushing portion and a body portion defining a guiding groove therein;
wherein one end of the body portion is retained on the guiding arm and the other end of the body portion is retained by the bracket, so the bracket keeps the pushing mechanism being retained on the guiding arm.

2. The electrical card connector as described in claim 1, wherein the bracket comprises a retaining portion and the retaining portion is inserted into a receiving slot defined at one end of the body portion.

3. The electrical card connector as described in claim 2, wherein the bracket comprises a top wall, a bottom wall and a side wall connecting the top wall and bottom wall, a pair of said retaining portions are respectively formed on a front portion of the top wall and the bottom wall, and a pair of said receiving slots are respectively defined on the end of the body portion.

4. The electrical card connector as described in claim 3, wherein the front portions of the upper wall and lower wall are in a fork shape, and said retaining portion is formed at one side of the front portion adjacent to the side wall and a first locking portion is formed opposite to the retaining portion.

5. The electrical card connector as described in claim 4, wherein a pair of second locking portions and third locking portions are respectively formed on the upper and lower walls behind the first locking portions, the second locking portions and the third locking portions are similar to the first locking portions and assembled on the guiding arms.

6. The electrical card connector as described in claim 5, wherein the pushing mechanism comprises a pushing rod, one end of the pushing rod is received in the bracket and the other end of the pushing rod is connecting with the pushing portion.

7. The electrical card connector as described in claim 6, wherein the pushing portion comprises a connecting portion at one distal end, the ejecting mechanism is connecting with the connecting portion.

8. The electrical card connector as described in claim 7, wherein a receiving portion is formed on the body portion opposite the receiving slot, said connecting portion surpasses the receiving portion to connect with the ejecting mechanism.

9. The electrical card connector as described in claim 1, wherein a metallic shell is provided to cover the connector body, the shell comprises a base portion and two side walls extending downwardly from sides of the base portion, the side walls form the guiding arms.

10. The electrical card connector as described in claim 2, wherein a solder pad is assembled on the guiding arm and partly received in an aperture defined on the body portion opposite to said receiving slot.

11. The electrical card connector as described in claim 2, wherein a tab is stamped from the guiding arm, the tab is received in an aperture defined on the body portion opposite to the receiving slot.

12. A card connector comprising:
an insulative housing having a plurality of contacts therein;
a body portion being located on one side of the housing and defining a heart like guiding groove therein;
a driving device back and forth moveable relative to the body portion;
a slider defining one end attached to the driving device and the other end guidably received in the guiding groove; and
a resilient supporting board positioned between the driving device and the guiding groove to urge said slider to be reliably retainably moveable in said guiding groove.
